(19) United States
(12) Patent Application Publication
(10) Pub. No.: US 2022/0216439 A1
(43) Pub. Date: Jul. 7, 2022

(54) PHOTOELECTRIC CONVERSION FILM, SOLAR CELL USING SAME, AND METHOD FOR PRODUCING PHOTOELECTRIC CONVERSION FILM

(71) Applicant: Panasonic Intellectual Property Management Co., Ltd., Osaka (JP)

(72) Inventors: MAKI HIRAOKA, Nara (JP); RYUUSUKE UCHIDA, Hyogo (JP); TORU NAKAMURA, Osaka (JP)

(21) Appl. No.: 17/700,952

(22) Filed: Mar. 22, 2022

Related U.S. Application Data
(63) Continuation of application No. PCT/JP2020/037789, filed on Oct. 6, 2020.

(30) Foreign Application Priority Data
Oct. 23, 2019 (JP) 2019-193050

(51) Int. Cl. H01L 51/42; H01L 51/00; C07F 13/00

(52) U.S. Cl. CPC H01L 51/4213; H01L 51/441; C07F 13/00; H01L 51/0026

(57) ABSTRACT

A photoelectric conversion film according to the present disclosure includes a perovskite compound including a monovalent formamidinium cation, a Pb cation and an iodide ion, and a substance having Hansen solubility parameters satisfying a dispersion term δ_{D} of 20±0.5 MPa^{0.5}, a polar term δ_{P} of 18±1 MPa^{0.5} and a hydrogen bonding term δ_{H} of 11±2 MPa^{0.5}.

### BACKGROUND

### 1. Technical Field

The present disclosure relates to a photoelectric conversion film, a solar cell using the photoelectric conversion film, and a method for producing photoelectric conversion films.

### 2. Description of the Related Art

In recent years, perovskite solar cells have been researched and developed. In perovskite solar cells, a photoelectric conversion material is used that is a perovskite compound represented by the chemical formula AMX₃ (where A is a monovalent cation, M is a divalent cation, and X is a halogen anion).

Perovskite solar cells have a stack structure that includes two electrodes opposed to each other and a photoelectric conversion layer disposed between the electrodes which absorbs light and generates separate charges. The photoelectric conversion layer is a perovskite layer including a perovskite compound. For example, the perovskite compound represented by HC(NH₂)₂PbI₃ (hereinafter, written as “FAPbI₃”) may be used.

In particular, high photoelectric conversion efficiency is exhibited by lead-based perovskite solar cells that have a perovskite layer including a lead-based perovskite compound represented by the chemical formula AMX₃ in which M is lead. For example, lead-based perovskite solar cells achieving efficiency as high as more than 20% have been reported. For example, the crystal structures of lead-based perovskite compounds such as FAPbI₃ include black α-phase known as belonging to the space group P3m1, and yellow δ-phase known as belonging to the space group P63mc. The δ-phase is a structural isomer of the α-phase. The δ-phase does not exhibit photoelectric conversion characteristics near room temperature. In contrast, the α-phase exhibits a high photoelectric conversion capability and has a bandgap of 1.4 eV. This value of bandgap is smallest among all the lead-based perovskite compounds. This value of bandgap is equal to the energy gap at which sunlight is absorbed most efficiently. Thus, perovskite layers including FAPbI₃ hold promise for the fabrication of more efficient solar cells among other perovskite layers including a lead-based perovskite compound.

Jeon, Nature 517, (2015) p. 476, and Fang, Light: Science & Applications 5, (2016) e16056 disclose methods for producing FAPbI₃ thin films. These literatures suggest that perovskite solar cells having high conversion efficiency may be fabricated by using FAPbI₃ in perovskite layers in the solar cells.

Japanese Unexamined Patent Application Publication No. 2019-55916 discloses a solar cell that has a perovskite layer including a complex including a perovskite compound and sulfolane. In the perovskite layer disclosed in Japanese Unexamined Patent Application Publication No. 2019-55916, the perovskite compound is present as a complex.

### SUMMARY

To improve the light absorption ability, an increased film thickness is required of a perovskite layer including a lead-based perovskite compound. However, increasing the film thickness of a perovskite layer is often accompanied by a decrease in carrier life.

One non-limiting and exemplary embodiment provides a photoelectric conversion film having a long carrier life.

In one general aspect, the techniques disclosed here feature a photoelectric conversion film including an α-phase perovskite compound including a monovalent formamidinium cation, a Pb cation and an iodide ion, and a substance having Hansen solubility parameters satisfying a dispersion term δ_{D} of 20±0.5 MPa^{0.5}, a polar term δ_{P} of 18±1 MPa^{0.5} and a hydrogen bonding term δ_{H} of 11±2 MPa^{0.5}.

The photoelectric conversion film provided according to the present disclosure has a long carrier life.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a schematic sectional view of a photoelectric conversion film for illustrating the outline of a method for producing a photoelectric conversion film according to the first embodiment of the present disclosure;

FIG. 1B is a schematic sectional view of a photoelectric conversion film for illustrating the outline of a method for producing a photoelectric conversion film according to the first embodiment of the present disclosure;

FIG. 2A is a schematic view illustrating an example method for producing a photoelectric conversion film according to the first embodiment of the present disclosure;

FIG. 2B is a schematic view illustrating an example method for producing a photoelectric conversion film according to the first embodiment of the present disclosure;

FIG. 2C is a schematic view illustrating an example method for producing a photoelectric conversion film according to the first embodiment of the present disclosure;

FIG. 2D is a schematic view illustrating an example method for producing a photoelectric conversion film according to the first embodiment of the present disclosure;

FIG. 3 is a sectional view schematically illustrating a first example of solar cells according to the second embodiment of the present disclosure;

FIG. 4 is a sectional view schematically illustrating a second example of solar cells according to the second embodiment of the present disclosure;

FIG. 5 is a sectional view schematically illustrating a third example of solar cells according to the second embodiment of the present disclosure;

FIG. 6 illustrates a scanning electron microscope (SEM) image of a cross section of a photoelectric conversion film of EXAMPLE 1-1;

FIG. 7 illustrates a SEM image of a cross section of a photoelectric conversion film of COMPARATIVE EXAMPLE 1-4;

FIG. 8A illustrates a SEM image of a cross section of a photoelectric conversion film of COMPARATIVE EXAMPLE 5-2;

FIG. 8B illustrates a SEM image of a cross section of the photoelectric conversion film of COMPARATIVE EXAMPLE 5-2;

FIG. 9 illustrates fluorescence attenuation curves of photoelectric conversion films of EXAMPLE 1-2, COMPARATIVE EXAMPLE 1-4, COMPARATIVE EXAMPLE 2-2 and COMPARATIVE EXAMPLE 5-4;

FIG. 10A illustrates results of selective ion analysis of dimethyl sulfoxide by a gas chromatography mass spectrometry (GC/MS) method with respect to a photoelectric conversion film of EXAMPLE 1-1;

FIG. 10B illustrates results of selective ion analysis of γ-butyrolactone by a GC/MS method with respect to the photoelectric conversion film of EXAMPLE 1-1;

FIG. 10C illustrates results of selective ion analysis of sulfolane by a GC/MS method with respect to the photoelectric conversion film of EXAMPLE 1-1;

FIG. 11 illustrates results of scan analysis of the photoelectric conversion film of EXAMPLE 1-1 by a GC/MS method;

FIG. 12A illustrates results of selective ion analysis of dimethyl sulfoxide by a GC/MS method with respect to a photoelectric conversion film of COMPARATIVE EXAMPLE 1-4;

FIG. 12B illustrates results of selective ion analysis of γ-butyrolactone by a GC/MS method with respect to the photoelectric conversion film of COMPARATIVE EXAMPLE 1-4;

FIG. 12C illustrates results of selective ion analysis of sulfolane by a GC/MS method with respect to the photoelectric conversion film of COMPARATIVE EXAMPLE 1-4;

FIG. 13 illustrates results of scan analysis of the photoelectric conversion film of COMPARATIVE EXAMPLE 1-4 by a GC/MS method; and

FIG. 14 is a graph illustrating relationships between the incident light wavelength and the external quantum efficiency (EQE) in solar cells of EXAMPLE 2 and COMPARATIVE EXAMPLE 6.

### DETAILED DESCRIPTIONS

### Definition of Terms

As used herein, the term “perovskite compound” means a perovskite crystal structure represented by the chemical formula ABX₃ (wherein A is a monovalent cation, B is a divalent cation and X is a halogen anion) or a structure having a similar crystal.

As used herein, the term “perovskite layer” means a layer including a perovskite compound.

As used herein, the term “lead-based perovskite compound” means a perovskite compound containing lead.

As used herein, the term “lead-based perovskite solar cell” means a solar cell that includes a lead-based perovskite compound as a photoelectric conversion material.

### Embodiments of the Present Disclosure

Hereinbelow, embodiments of the present disclosure will be described in detail with reference to the drawings.

### First Embodiment

A photoelectric conversion film according to the first embodiment of the present disclosure includes an α-phase perovskite compound including a monovalent formamidinium cation (that is, NH₂CHNH₂⁺), a Pb cation and an iodide ion, and a substance having Hansen solubility parameters (hereinafter, HSP) described below (hereinafter, the substance will be written as the substance (A)).

HSP (δ_{D}: dispersion term, δ_{P}: polar term, δ_{H}: hydrogen bonding term)

δ_{D}=20±0.5 MPa^{0.5}

δ_{P}=18±1 MPa^{0.5}

δ_{H}=11±2 MPa^{0.5}

Hereinbelow, the α-phase perovskite compound described above may be written as the “perovskite compound according to the present embodiment”, and the HSP described above may be written as the “HSP according to the present embodiment”.

The photoelectric conversion film according to the present embodiment includes a perovskite compound according to the present embodiment and also a substance (A) having HSP according to the present embodiment. By virtue of this configuration, the photoelectric conversion film according to the present embodiment may attain high quality and excellent flatness even when the film thickness is large. Thus, the photoelectric conversion film according to the present embodiment offers a long carrier life even when the film thickness is large.

The perovskite compound contained in the photoelectric conversion film according to the present embodiment has an α-phase. α-Phase perovskite compounds exhibit a high photoelectric conversion capability and have a low bandgap. When, for example, the perovskite compound according to the present embodiment is FAPbI₃, the α-phase FAPbI₃ has a bandgap of 1.4 eV. This value of bandgap is smallest among all the lead-based perovskite compounds. By virtue of having such a low bandgap, the perovskite compound according to the present embodiment can efficiently absorb sunlight.

The substance (A) may be at least one selected from the group consisting of sulfolane and maleic anhydride. Sulfolane has HSP in which the dispersion term δ_{D} is 20.3 MPa^{0.5}, the polar term δ_{P} is 18.2 MPa^{0.5} and the hydrogen bonding term δ_{H} is 10.8 MPa^{0.5}. Maleic anhydride has HSP in which the dispersion term δ_{D} is 20.2 MPa^{0.5}, the polar term δ_{P} is 18.1 MPa^{0.5} and the hydrogen bonding term δ_{H} is 12.6 MPa^{0.5}. When the substance (A) is sulfolane and/or maleic anhydride, defects in the perovskite structure stemming from this substance (A) are unlikely to serve as carrier recombination sites. Thus, a long carrier life may be realized when the photoelectric conversion film according to the present embodiment includes sulfolane and/or maleic anhydride as the substance (A).

Defects in the perovskite structure stemming from sulfolane are particularly unlikely to serve as carrier recombination sites. Thus, a long carrier life may be realized more efficiently when the photoelectric conversion film according to the present embodiment includes sulfolane as the substance (A).

In the photoelectric conversion film according to the present embodiment, the content of the substance (A) may be less than or equal to 0.1 mol %. The photoelectric conversion film according to the present embodiment contains more than 0 mol % of the substance (A).

When the photoelectric conversion film according to the present embodiment contains sulfolane as the substance (A), the photoelectric conversion film according to the present embodiment has peaks at m/z=41, 56 and 120 when analyzed by a GC/MS method.

The substance (A) may be a solvent that is contained in a solution used in the production of the photoelectric conversion film according to the present embodiment. When the substance (A) is a solvent used at the time of film production, the photoelectric conversion film according to the present embodiment may be produced by leaving a desired amount of the solvent in the film that is produced.

In general, perovskite compounds are represented by, for example, the chemical formula AMX₃. In the chemical formula, A denotes a monovalent cation, M a divalent cation, and X a halogen anion. In line with the commonly used expressions in perovskite compounds, A, M and X in the present specification are also written as A-site, M-site and X-site, respectively. The perovskite compound according to the present embodiment is composed of a monovalent formamidinium cation, a Pb cation and an iodide ion. Thus, the perovskite compound according to the present embodiment is a perovskite compound represented by, for example, the chemical formula HC(NH₂)₂PbI₃ (that is, FAPbI₃). Here, FAPbI₃ has FA:Pb:I=1:1:3, but the composition may be slightly different as long as the A-site, the M-site and the X-site principally include FA, Pb and I, respectively.

The photoelectric conversion film according to the present embodiment may include the perovskite compound according to the present embodiment in a major proportion. Here, the phrase “the photoelectric conversion film includes the perovskite compound according to the present embodiment in a major proportion” means that the perovskite compound according to the present embodiment represents greater than or equal to 70 mol % of all the substances constituting the photoelectric conversion film. For example, this proportion may be greater than or equal to 80 mol %.

The photoelectric conversion film according to the present embodiment may include a material other than the perovskite compounds according to the present embodiment. For example, the photoelectric conversion film according to the present embodiment may include a trace amount of a perovskite compound which is different from FAPbI₃ and is represented by the chemical formula A2M2X2₃. A2 is a monovalent cation. For purposes such as to enhance durability, A2 may include a trace amount of such a monovalent cation as an alkali metal cation or an organic cation. More specifically, A2 may include a trace amount of methylammonium cation (CH₃NH₃⁺) and/or cesium cation (Cs⁺). M2 is a divalent cation. For purposes such as to enhance durability, M2 may include a trace amount of a transition metal and/or a divalent, Group 13 to Group 15 element cation. Specific examples include Pb²⁺, Ge²⁺ and Sn²⁺. X2 is a monovalent anion such as a halogen anion. The cation A2-site, the cation M2-site and the anion X2-site may be each occupied by trace amounts of a plurality of kinds of ions. Specific examples of the perovskite compounds different from FAPbI₃ include CH₃NH₃PbI₃, CH₃CH₂NH₃PbI₃, CH₃NH₃PbBr₃, CH₃NH₃PbCl₃, CsPbI₃ and CsPbBr₃.

The photoelectric conversion film according to the present embodiment may have a film thickness of greater than or equal to 1 μm. Depending on, for example, use application, the film thickness of the photoelectric conversion film according to the present embodiment may be appropriately selected from the range of greater than or equal to 1 μm and less than or equal to 100 μm. The photoelectric conversion film according to the present embodiment may attain a long carrier life even when the film thickness is as large as greater than or equal to 1 μm. As described above, the photoelectric conversion film according to the present embodiment may be increased in film thickness while maintaining a long carrier life. When the film thickness of the photoelectric conversion film according to the present embodiment is increased to, for example, greater than or equal to 1 μm, the photoelectric conversion film according to the present embodiment can also absorb light in the band of 1.4 eV to 1.5 eV. On the other hand, a conventional photoelectric conversion film containing a perovskite compound suffers a short carrier life when the film thickness is increased, and consequently the film thickness is necessarily limited to about several hundreds of nm in order to ensure that the generated carriers will be taken out. Due to this fact, light absorption by a conventional photoelectric conversion film containing a perovskite compound is disadvantageously limited to about 1.5 eV of solar energy. In contrast, the photoelectric conversion film according to the present embodiment can concurrently achieve a long carrier life and a large film thickness of, for example, greater than or equal to 1 μm. Thus, the photoelectric conversion film according to the present embodiment can absorb an increased amount of light as compared with a conventional photoelectric conversion film, and can attain a high light absorption ability. When the photoelectric conversion film according to the present embodiment is used in a solar cell, the solar cell generates an increased amount of carriers by the increase in spectrum band of light that can be absorbed, and the generated carriers can be taken out while taking advantage of the long carrier life. Thus, the photoelectric conversion film according to the present embodiment allows the solar cell to achieve higher conversion efficiency.

The film thickness of the photoelectric conversion film according to the present embodiment may be less than or equal to 3.4 μm. When the film thickness of the photoelectric conversion film is less than or equal to 3.4 μm, the surface roughness of the photoelectric conversion film may be further reduced and the film quality may be enhanced. Thus, the carrier life may be further extended when the film thickness of the photoelectric conversion film according to the present embodiment is less than or equal to 3.4 μm.

In the photoelectric conversion film according to the present embodiment, the ratio of the root mean square roughness Rq to the film thickness may be, for example, less than or equal to 0.13. When the photoelectric conversion film according to the present embodiment has such a small surface roughness, the photoelectric conversion film according to the present embodiment may achieve a longer carrier life.

Here, the root mean square roughness Rq is measured in accordance with JIS B 0601: 2013. For example, three 500 μm wide profiles are measured using a surface shape measuring device, and are each assessed to determine the root mean square roughness. The root mean square roughnesses measured with respect to the three points are averaged to give the root mean square roughness Rq. The film thickness of the photoelectric conversion film is determined using a surface shape measuring device. For example, three 500 μm wide profiles are measured using a surface shape measuring device. With respect to each of the profiles, three values in total of height from the substrate are averaged. The average values of height from the substrate, each measured with respect to the three points, are further averaged to determine the film thickness of the photoelectric conversion film.

In the photoelectric conversion film according to the present embodiment, the ratio of the root mean square roughness Rq to the film thickness may be less than or equal to 0.1. The photoelectric conversion film of the present embodiment may have smaller surface roughness that satisfies a ratio of the root mean square roughness Rq to the film thickness of less than or equal to 0.1. As a result of this configuration, the shortening of carrier life is improved more efficiently and a longer carrier life may be realized.

In the photoelectric conversion film according to the present embodiment, the ratio of the root mean square roughness Rq to the film thickness may be greater than or equal to 0.07. This configuration ensures that the photoelectric conversion film according to the present embodiment will have a minimum size of crystal grains that is necessary for realizing a long carrier life. Thus, the film may attain a long carrier life and greater flatness.

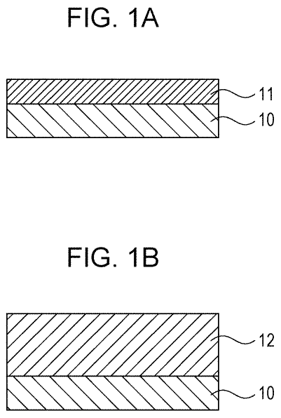

Next, an embodiment of a method for producing a photoelectric conversion film according to the present embodiment will be described. FIGS. 1A and 1B are schematic sectional views of a photoelectric conversion film for illustrating the outline of the method for producing a photoelectric conversion film according to the present embodiment.

The method for producing a photoelectric conversion film according to the present embodiment includes the following steps:

(A) a first solution including elements for constituting a first perovskite compound is applied to a substrate 10 to form a seed layer 11 including the first perovskite compound (see FIG. 1A); and
(B) the substrate 10 is heated and a second solution is brought into contact with the surface of the seed layer 11 on the substrate 10 to precipitate a second perovskite compound, thereby producing a photoelectric conversion film 12 (see FIG. 1B).

Here, the second solution includes elements for constituting a second perovskite compound, and a solvent. The elements for constituting a second perovskite compound include a monovalent formamidinium cation, a Pb cation and an iodide ion. The solvent includes a substance (A) that has HSP satisfying a dispersion term δ_{D} of 20±0.5 MPa^{0.5}, a polar term δ_{P} of 18±1 MPa^{0.5} and a hydrogen bonding term δ_{H} of 11±2 MPa^{0.5}.

The above production method according to the present embodiment starts with the step (A) in which a seed layer 11 composed of a first perovskite compound is formed on a substrate 10. Next, in the step (B), a second solution is brought into contact with the surface of the seed layer 11 disposed on the substrate 10 to precipitate a second perovskite compound, thereby forming a photoelectric conversion film 12. In the step (B), the substrate 10 is allowed to stand while the second solution is in contact with the surface of the seed layer 11 disposed on the substrate 10 and while performing heating of the substrate 10. In this manner, the seed layer 11 dissipates into the second solution and concurrently the second perovskite compound is precipitated, and thereby the photoelectric conversion film 12 is obtained. That is, the second perovskite compound corresponds to the perovskite compound according to the present embodiment. The photoelectric conversion film 12 produced by the above method attains small surface roughness and excellent quality even when formed with a large film thickness. Thus, the photoelectric conversion film 12 that is obtained attains a long carrier life even when formed with a large film thickness. In the photoelectric conversion film 12 that is obtained, the substance (A) used as the solvent remains. Thus, the photoelectric conversion film 12 produced by the production method according to the present embodiment also contains the substance (A).

The step (A) and the step (B) will be described in more detail below.

The seed layer 11 formed in the step (A) is composed of a first perovskite compound. For example, the first perovskite compound forming the seed layer 11 may be a perovskite compound represented by the chemical formula A1M1X1₃. In the chemical formula A1M1X1₃, A1 is at least one selected from the group consisting of monovalent formamidinium cation, monovalent methylammonium cation, monovalent cesium cation and monovalent rubidium cation. M1 is at least one selected from the group consisting of Pb cation and Sn cation. X1 is a halogen anion.

When the seed layer 11 is composed of a perovskite compound represented by the chemical formula A1M1X1₃, a second perovskite compound is easily precipitated in the step (B) and will form a photoelectric conversion film having good film quality.

The first solution used to form the seed layer 11 includes elements for constituting the first perovskite compound. When the first perovskite compound is a perovskite compound represented by the chemical formula A1M1X1₃, the first solution includes, for example, compounds M1X1₂ and A1X1 as raw materials for A1M1X1₃, and a solvent. The solvent may be any solvent that can dissolve the raw materials M1X1₂ and A1X1. For example, an organic solvent may be used. Examples of the organic solvents include alcohol solvents, amide solvents, nitrile solvents, hydrocarbon solvents and lactone solvents. A mixture of two or more kinds of these solvents may be used. The solvent may contain an additive. Such an additive may induce crystal nucleation and promote crystal growth. Examples of the additives include hydrogen iodide, amines and surfactants.

The first perovskite compound may be a compound that is the same as or different from the second perovskite compound contained in the photoelectric conversion film that will be produced.

For example, the first solution may be applied onto the substrate 10 by a coating method such as a spin coating method or a dip coating method, or a printing method. When the photoelectric conversion film 12 formed by the production method according to the present embodiment is a photoelectric conversion layer in a solar cell, for example, the substrate 10 may be a substrate having an electrode layer on its surface or may be a substrate having on its surface a stack of an electrode layer and a carrier transport layer (for example, a hole transport layer or an electron transport layer) in this order.

Next, the substrate 10 wet with the first solution is heated to, for example, a first temperature to dry the first solution sitting on the surface. The first temperature may be any temperature at which the solvent of the first solution can be dried. For example, an example of the first temperature is greater than or equal to 100° C. and less than or equal to 180° C. In this manner, as illustrated in FIG. 1A, a seed layer 11 composed of a first perovskite compound is formed.

For example, the thickness of the seed layer 11 may be greater than or equal to 10 nm and less than or equal to 100 nm. When formed with a thickness of greater than or equal to 10 nm, the seed layer may attain enhanced functions. When, on the other hand, the seed layer is formed with a thickness of less than or equal to 100 nm, residues of the seed layer may be easily eliminated. That is, a photoelectric conversion film 12 free from a residual seed layer may be easily formed.

Next, the step (B) is performed. Specifically, a photoelectric conversion film 12 is formed on the substrate 10.

A second solution for forming a photoelectric conversion film 12 is provided. The second solution includes elements for constituting a second perovskite compound. The second perovskite compound corresponds to the perovskite compound according to the present embodiment described hereinabove that is contained in the photoelectric conversion film according to the present embodiment. That is, the second perovskite compound is composed of a monovalent formamidinium cation, a Pb cation and an iodide ion. The second perovskite compound is, for example, a perovskite compound represented by the chemical formula FAPbI₃. In this case, the second solution includes elements for constituting FAPbI₃. For example, the second solution includes compounds PbI₂ and FAI as raw materials for FAPbI₃, and a solvent. As described hereinabove, the solvent in the second solution includes a substance (A) that has HSP satisfying a dispersion term δ_{D} of 20±0.5 MPa^{0.5}, a polar term δ_{P} of 18±1 MPa^{0.5} and a hydrogen bonding term δ_{H} of 11±2 MPa^{0.5}. For example, the substance (A) may be at least one selected from the group consisting of sulfolane and maleic anhydride, or may be sulfolane.

PbI₂ has HSP in which the dispersion term δ_{D} is 18.8 MPa^{0.5}, the polar term δ_{P} is 11.7 MPa^{0.5} and the hydrogen bonding term δ_{H} is 12.3 MPa^{0.5}. FAI has HSP in which the dispersion term δ_{D} is 15.0 MPa^{0.5}, the polar term δ_{P} is 21.3 MPa^{0.5} and the hydrogen bonding term δ_{H} is 22.2 MPa^{0.5}. In general, materials having a short distance R in the three-dimensional HSP space are similar in properties and are highly miscible, while materials having a long distance R are not compatible with each other and are separated. In the HSP space, the distance between a point for PbI₂ and a point for a given solvent is written as R (PbI₂), and the distance between a point for FAI and a point of a solvent is written as R (FAI). Inverse temperature crystallization (ITC) in which the solubility decreases with increasing temperature occurs in a narrow range where, for example, R (PbI₂) is 7 to 9 and R (FAI) is 16 to 18. In this range, the solubility is midpoint between soluble and insoluble, and PbI₂ is present as clusters in the solution. In particular, R (PbI₂)=7.3 and R (FAI)=15.8 in the case of sulfolane. That is, the affinity with the solvent is fairly high as compared with other levels of affinity under ITC-permitting conditions. At room temperature, sulfolane shows high solvent properties with respect to FAPbI₃ and the crystallization tendency is usual. On the other hand, ITC occurs at temperatures in the range of 95° C. and above. Thus, a photoelectric conversion film produced under such conditions will be of particularly high quality.

The solvent in the second solution may include a plurality of kinds of substances (A).

Next, the second solution is brought into contact with the surface of the seed layer 11 on the substrate 10. During this process, the substrate 10 is heated to a second temperature. The second temperature, to which the substrate 10 is heated at the time of contact between the seed layer 11 and the second solution, may be set to, for example, a temperature at which the second solution is saturated or supersaturated. In this manner, the seed layer 11 is immediately replaced by the second perovskite compound in the second solution. Then, the second perovskite compound grows on the substrate 10 to form a photoelectric conversion film 12. When, for example, the solvent contained in the second solution is sulfolane, the second solution is supersaturated in the range of greater than or equal to room temperature and less than or equal to 150° C. Thus, the second temperature may be set to, for example, less than or equal to 130° C. In the step (B), at least the substrate 10 should be heated to the second temperature, and the second solution may or may not be heated. When the second solution is heated, the heating temperature may be lower than the second temperature.

The film thickness of the photoelectric conversion film may be controlled by controlling the amount of time of contact between the seed layer 11 and the second solution (that is, the amount of time for which the second perovskite compound is precipitated).

As described above, the photoelectric conversion film 12 may be formed by precipitating the second perovskite compound, for example, FAPbI₃, on the substrate 10.

The thickness of the photoelectric conversion film 12 that is formed is not particularly limited and may be selected appropriately in accordance with the use application of the photoelectric conversion film 12. By the production method according to the present embodiment, a quality photoelectric conversion film 12 having a large thickness of greater than or equal to 1 μm may be formed with high flatness.

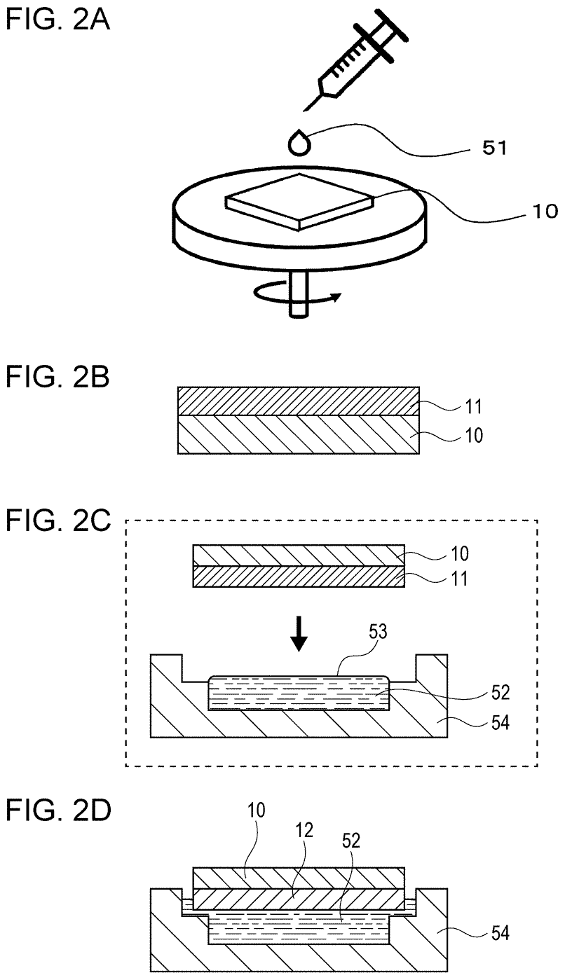

An example of the methods for producing a photoelectric conversion film according to the present embodiment will be further described in detail with reference to FIGS. 2A to 2D. FIGS. 2A to 2D are schematic views illustrating an example of the methods for producing a photoelectric conversion film according to the present embodiment.

As illustrated in FIG. 2A, a first solution 51 is applied onto a substrate 10 by, for example, a spin coating method. Next, the substrate 10 coated with the first solution 51 is heated to dry the coating film of the first solution 51 on the substrate 10. In this manner, as illustrated in FIG. 2B, a seed layer 11 composed of a first perovskite compound is formed.

Next, as illustrated in FIG. 2C, a second solution 52 is held in a container 54, and the substrate 10 on which the seed layer 11 is disposed is approximated thereto to bring the surface of the seed layer 11 into contact with the surface 53 of the second solution 52. For example, a second solution 52 including PbI₂ and FAI is heated to a second temperature (for example, 100° C.), and the surface of the seed layer 11 on the substrate 10 that has been similarly heated to the second temperature is brought into contact with the surface 53 of the second solution 52. In this manner, the seed layer 11 is immediately replaced by FAPbI₃ in the second solution 52, and FAPbI₃ grows on the substrate 10. As a result, a photoelectric conversion film 12 is formed on the substrate 10 as illustrated in FIG. 2D. Incidentally, the heating temperature for the second solution 52 may be lower than the second temperature, or the second solution 52 may not be heated.

The method for producing a photoelectric conversion film according to the present embodiment is not limited to the above. For example, a photoelectric conversion film may also be produced by a known coating method such as a spin coating method. When a photoelectric conversion film having a large film thickness is to be produced, the production method according to the present embodiment described above may be used for the reasons that the film that is obtained has high flatness and higher quality.

### Second Embodiment

A solar cell according to the second embodiment of the present disclosure includes a first electrode, a second electrode and a photoelectric conversion layer. The photoelectric conversion layer is disposed between the first electrode and the second electrode. At least one electrode selected from the group consisting of the first electrode and the second electrode has translucency. The photoelectric conversion layer is the photoelectric conversion film described in the first embodiment. That is, the photoelectric conversion layer in the solar cell according to the second embodiment is a photoelectric conversion film which includes a perovskite compound including a monovalent formamidinium cation, a Pb cation and an iodide ion, and a substance (A) having HSP satisfying a dispersion term δ_{D} of 20±0.5 MPa^{0.5}, a polar term δ_{P} of 18±1 MPa^{0.5} and a hydrogen bonding term δ_{H} of 11±2 MPa^{0.5}.

The photoelectric conversion layer in the solar cell according to the present embodiment is a photoelectric conversion film that has the above configuration and thus offers a long carrier life. As described in the first embodiment, this photoelectric conversion film may attain a long carrier life even when the film thickness is increased. As a result of the photoelectric conversion film having an increased film thickness, the solar cell that is obtained can absorb light in a wider spectrum band and attains enhancements in light absorption ability. As a result, the solar cell generates an increased amount of carriers and may realize high conversion efficiency.

### (First Example of Solar Cells)

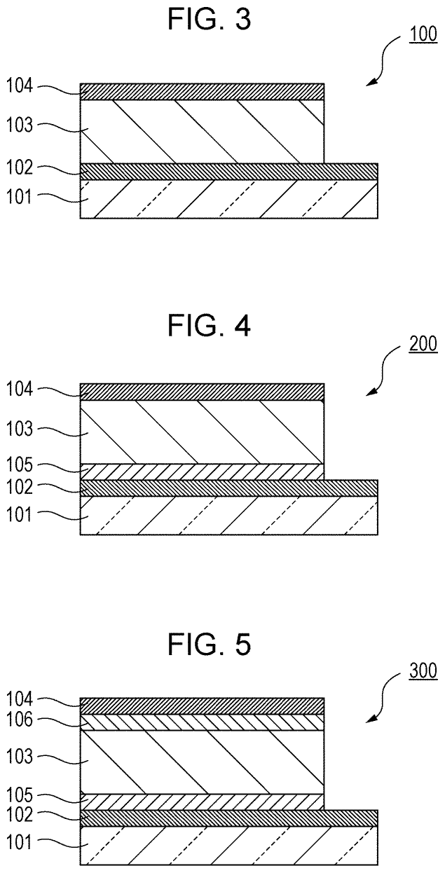

FIG. 3 is a sectional view schematically illustrating a first example of the solar cells according to the second embodiment of the present disclosure.

In a solar cell 100 illustrated in FIG. 3, a first electrode 102, a photoelectric conversion layer 103 and a second electrode 104 are stacked in this order on a substrate 101. The solar cell 100 may not have the substrate 101.

Next, the basic working effects of the solar cell 100 will be described. When the solar cell 100 is irradiated with light, the photoelectric conversion layer 103 absorbs the light and generates excited electrons and holes. The excited electrons move to the first electrode 102 that is a negative electrode. On the other hand, the holes generated in the photoelectric conversion layer 103 move to the second electrode 104 that is a positive electrode. In this manner, the solar cell 100 can produce an electric current from the negative electrode and the positive electrode. While this example illustrates the first electrode 102 as functioning as the negative electrode and the second electrode 104 as functioning as the positive electrode, the first electrode 102 may function as the positive electrode and the second electrode 104 may function as the negative electrode.

For example, the solar cell 100 may be fabricated by the following method. First, a first electrode 102 is formed on the surface of a substrate 101 by a sputtering method or the like. Next, a photoelectric conversion layer 103 that is a photoelectric conversion film according to the first embodiment is formed by the method described in the first embodiment. Next, a second electrode 104 is formed on the photoelectric conversion layer 103 by a sputtering method or the like.

The components constituting the solar cell 100 will be described in detail hereinbelow.

### (Substrate 101)

The substrate 101 supports other layers in the solar cell 100. The substrate 101 may be formed from a transparent material. For example, a glass substrate or a plastic substrate may be used. The plastic substrate may be, for example, a plastic film. When the first electrode 102 has sufficient strength, the substrate 101 is not necessarily provided because the first electrode 102 can support other layers.

### (First Electrode 102 and Second Electrode 104)

The first electrode 102 and the second electrode 104 have conductivity. At least one of the first electrode 102 and the second electrode 104 is translucent. As used herein, the phrase “the electrode is translucent” means that the electrode transmits at least 10% of light having wavelengths of greater than or equal to 200 nm and less than or equal to 2000 nm, at any of these wavelengths.

For example, the translucent electrode may transmit light from the visible region to the near infrared region. The translucent electrode may be formed from at least one of transparent and conductive metal oxides and metal nitrides.

Examples of the metal oxides include:

(i) titanium oxides doped with at least one selected from the group consisting of lithium, magnesium, niobium and fluorine,

(ii) gallium oxides doped with at least one selected from the group consisting of tin and silicon,

(iii) indium-tin composite oxides,

(iv) tin oxides doped with at least one selected from the group consisting of antimony and fluorine, and

(v) zinc oxides doped with at least one selected from the group consisting of boron, aluminum, gallium and indium.

Two or more kinds of metal oxides may be used in combination as a composite.

Examples of the metal nitrides include gallium nitrides doped with at least one selected from the group consisting of silicon and oxygen. Two or more kinds of metal nitrides may be used in combination.

The metal oxides and the metal nitrides may be used in combination.

The translucent electrode may be formed using a non-transparent material so as to form a light-transmitting pattern. Examples of the light-transmitting patterns include linear patterns, wavy patterns, grid patterns, and punching metal-like patterns in which a large number of micro through-holes are regularly or irregularly arranged. When the electrode has such a pattern, light can be transmitted through regions where there is no electrode material. Examples of the non-transparent materials include platinum, gold, silver, copper, aluminum, rhodium, indium, titanium, iron, nickel, tin, zinc, and alloys containing any of these metals. Further, conductive carbon materials may also be used.

In the solar cell 100, the first electrode 102 is in contact with the photoelectric conversion layer 103. Thus, the first electrode 102 is formed of a material that has hole-blocking properties to block holes moving from the photoelectric conversion layer 103. In this case, the first electrode 102 does not make ohmic contact with the photoelectric conversion layer 103. The hole-blocking properties by which holes moving from the photoelectric conversion layer 103 are blocked mean that the electrode allows for the passage of only electrons generated in the photoelectric conversion layer 103 and blocks the passage of holes. The Fermi energy level of the material having the hole-blocking properties may be higher than the energy level at the upper end of the valence band with the photoelectric conversion layer 103. Examples of such materials include aluminum.

In the solar cell 100, the second electrode 104 is in contact with the photoelectric conversion layer 103. Thus, the second electrode 104 is formed of a material that has electron-blocking properties to block electrons moving from the photoelectric conversion layer 103. In this case, the second electrode 104 does not make ohmic contact with the photoelectric conversion layer 103. The electron-blocking properties by which electrons moving from the photoelectric conversion layer 103 are blocked mean that the electrode allows for the passage of only holes generated in the photoelectric conversion layer 103 and blocks the passage of electrons. The Fermi energy level of the material having the electron-blocking properties is lower than the energy level at the lower end of the conduction band of the photoelectric conversion layer 103. The Fermi energy level of the material having the electron-blocking properties may be lower than the Fermi energy level of the photoelectric conversion layer 103. Specifically, the second electrode 104 may be formed from platinum, gold or a carbon material such as graphene. These materials have electron-blocking properties but do not have translucency. Thus, when a translucent second electrode 104 is to be formed using such a material, a light-transmitting pattern such as one described hereinabove is formed in the second electrode 104.

The light transmittance of the translucent electrode may be greater than or equal to 50%, or greater than or equal to 80%. The wavelength of light transmitted through the electrode depends on the wavelength absorbed by the photoelectric conversion layer 103. The thicknesses of the first electrode 102 and the second electrode 104 are, for example, each greater than or equal to 1 nm and less than or equal to 1000 nm.

### (Photoelectric Conversion Layer 103)

The photoelectric conversion layer 103 is the photoelectric conversion film according to the first embodiment. Thus, detailed description is omitted.

### (Second Example of Solar Cells)

A modified example of the solar cells according to the second embodiment of the present disclosure will be described.

FIG. 4 is a sectional view schematically illustrating a second example of the solar cells according to the second embodiment of the present disclosure. A solar cell 200 illustrated in FIG. 4 differs from the solar cell 100 shown in FIG. 3 in that an electron transport layer 105 is present. The components having the same functions and configurations as in the solar cell 100 are designated by numerals common to those in the solar cell 100, and the description thereof will be omitted.

In the solar cell 200 illustrated in FIG. 4, a first electrode 102, an electron transport layer 105, a photoelectric conversion layer 103 and a second electrode 104 are stacked in this order on a substrate 101.

Next, the basic working effects of the solar cell 200 will be described. When the solar cell 200 is irradiated with light, the photoelectric conversion layer 103 absorbs the light and generates excited electrons and holes. The excited electrons move through the electron transport layer 105 to the first electrode 102 that is a negative electrode. On the other hand, the holes generated in the photoelectric conversion layer 103 move to the second electrode 104 that is a positive electrode. In this manner, the solar cell 200 can produce an electric current from the negative electrode and the positive electrode.

The solar cell 200 may be fabricated by the same method as the solar cell 100 illustrated in FIG. 3. The electron transport layer 105 is formed on the first electrode 102 by a sputtering method or the like.

The components constituting the solar cell 200 will be described in detail hereinbelow.

### (First Electrode 102)

The first electrode 102 in the solar cell 200 is the same as the first electrode 102 in the solar cell 100. However, because the solar cell 200 includes the electron transport layer 105 between the photoelectric conversion layer 103 and the first electrode 102, the first electrode 102 does not necessarily have hole-blocking properties by which holes moving from the photoelectric conversion layer 103 are blocked. That is, the first electrode 102 may be formed of a material capable of forming an ohmic contact with the photoelectric conversion layer 103. Because the first electrode 102 in the solar cell 200 does not necessarily have hole-blocking properties, the material for the first electrode 102 may be selected from a wider range of materials.

### (Electron Transport Layer 105)

The electron transport layer 105 includes a semiconductor. The electron transport layer 105 may be a semiconductor having a bandgap of greater than or equal to 3.0 eV. By forming the electron transport layer 105 from a semiconductor having a bandgap of greater than or equal to 3.0 eV, visible light and infrared light may be transmitted to the photoelectric conversion layer 103. Examples of such semiconductors include organic n-type semiconductors and inorganic n-type semiconductors.

Examples of the organic n-type semiconductors include imide compounds, quinone compounds, fullerenes and fullerene derivatives. Examples of the inorganic n-type semiconductors include metal oxides, metal nitrides and perovskite oxides. Examples of the metal oxides include oxides of Cd, Zn, In, Pb, Mo, W, Sb, Bi, Cu, Hg, Ti, Ag, Mn, Fe, V, Sn, Zr, Sr, Ga, Si or Cr. Specific examples include TiO₂. Examples of the perovskite oxides include SrTiO₃ and CaTiO₃.

The electron transport layer 105 may include a substance having a bandgap greater than 6.0 eV. Examples of the substances having a bandgap greater than 6.0 eV include (i) halides of alkali metals or alkaline earth metals such as lithium fluoride and calcium fluoride, (ii) alkali metal oxides such as magnesium oxide, and (iii) silicon dioxide. In this case, the thickness of the electron transport layer 105 is, for example, less than or equal to 10 nm in order to ensure electron-transporting properties of the electron transport layer 105.

The electron transport layer 105 may include a plurality of layers made of different materials from one another.

### (Third Example of Solar Cells)

A modified example of the solar cells according to the second embodiment of the present disclosure will be described.

FIG. 5 is a sectional view schematically illustrating a third example of the solar cells according to the second embodiment of the present disclosure. A solar cell 300 illustrated in FIG. 5 differs from the solar cell 200 shown in FIG. 4 in that a hole transport layer 106 is present. The components having the same functions and configurations as in the solar cell 100 and the solar cell 200 are designated by numerals common to those in the solar cell 100 and the solar cell 200, and the description thereof will be omitted.

In the solar cell 300 illustrated in FIG. 5, a first electrode 102, an electron transport layer 105, a photoelectric conversion layer 103, a hole transport layer 106 and a second electrode 104 are stacked in this order on a substrate 101.

Next, the basic working effects of the solar cell 300 will be described. When the solar cell 300 is irradiated with light, the photoelectric conversion layer 103 absorbs the light and generates excited electrons and holes. The excited electrons move through the electron transport layer 105 to the first electrode 102 that is a negative electrode. On the other hand, the excited holes move through the hole transport layer 106 to the second electrode 104 that is a positive electrode. In this manner, the solar cell 300 can produce an electric current from the negative electrode and the positive electrode.

The solar cell 300 may be fabricated by the same method as the solar cell 200 illustrated in FIG. 4. The hole transport layer 106 is formed on the photoelectric conversion layer 103 by a coating method or the like.

The components constituting the solar cell 300 will be described in detail hereinbelow.

### (Second Electrode 104)

The second electrode 104 in the solar cell 300 is the same as the second electrode 104 in the solar cell 200. However, because the solar cell 300 includes the hole transport layer 106 between the photoelectric conversion layer 103 and the second electrode 104, the second electrode 104 does not necessarily have electron-blocking properties by which electrons moving from the photoelectric conversion layer 103 are blocked. That is, the second electrode 104 may be formed of a material capable of forming an ohmic contact with the photoelectric conversion layer 103. Because the second electrode 104 in the solar cell 300 does not necessarily have electron-blocking properties, the material for the second electrode 104 may be selected from a wider range of materials.

### (Hole Transport Layer 106)

The hole transport layer 106 is composed of an organic substance or an inorganic semiconductor. The hole transport layer 106 may include a plurality of layers made of different materials from one another.

Examples of the organic substances include phenylamines, triphenylamine derivatives and polytriarylamines (poly(bis(4-phenyl)(2,4,6-trimethylphenyl)amine: PTAA) each including a tertiary amine in the skeleton, and PEDOT (poly(3,4-ethylenedioxythiophene) compounds including a thiophene structure. The molecular weight is not particularly limited, and the organic substances may be polymers. When the hole transport layer 106 is formed using such an organic substance, the film thickness may be greater than or equal to 1 nm and less than or equal to 1000 nm, or may be greater than or equal to 100 nm and less than or equal to 500 nm. The film thickness in this range ensures that sufficient hole-transporting properties will be exhibited. The film thickness in the above range also ensures that low resistance will be maintained and the energy of light may be highly efficiently converted to electricity.

Examples of the inorganic semiconductors that may be used include p-type semiconductors such as CuO, Cu₂O, CuSCN, molybdenum oxide and nickel oxide. When the hole transport layer 106 is formed using such an inorganic semiconductor, the film thickness may be greater than or equal to 1 nm and less than or equal to 1000 nm, or may be greater than or equal to 10 nm and less than or equal to 50 nm. The film thickness in this range ensures that sufficient hole-transporting properties will be exhibited. The film thickness in the above range also ensures that low resistance will be maintained and the energy of light may be highly efficiently converted to electricity.

The hole transport layer 106 may be formed by a coating method or a printing method. Examples of the coating methods include doctor blade methods, bar coating methods, spraying methods, dip coating methods and spin coating methods. Examples of the printing methods include screen printing methods. Where necessary, a plurality of materials may be mixed to form a hole transport layer 106, and the hole transport layer 106 may be then pressed or heat-treated. When the material for the hole transport layer 106 is an organic low-molecular substance or an inorganic semiconductor, the hole transport layer 106 may be formed by a vacuum deposition method or the like.

The hole transport layer 106 may include a supporting electrolyte and a solvent. A supporting electrolyte and a solvent stabilize the holes in the hole transport layer 106.

Examples of the supporting electrolytes include ammonium salts and alkali metal salts. Examples of the ammonium salts include tetrabutylammonium perchlorate, tetraethylammonium hexafluorophosphate, imidazolium salts and pyridinium salts. Examples of the alkali metal salts include lithium perchlorate and potassium tetrafluoroborate.

The solvent contained in the hole transport layer 106 may have high ion conductivity. Any aqueous solvents and organic solvents may be used. To stabilize the solutes to a higher degree, the solvent may be an organic solvent. Examples of the organic solvents include heterocyclic compounds such as tert-butylpyridine, pyridine and n-methylpyrrolidone.

The solvent contained in the hole transport layer 106 may be an ionic liquid. An ionic liquid may be used alone or as a mixture with other solvents. Ionic liquids are preferable because of low volatility and high flame retardancy.

Examples of the ionic liquids include imidazolium compounds such as 1-ethyl-3-methylimidazolium tetracyanoborate, pyridine compounds, alicyclic amine compounds, aliphatic amine compounds and azonium amine compounds.

In the present specification, the thickness of each of the layers other than the photoelectric conversion film may be an average of values measured at an appropriate number of points (for example, 5 points). The thickness of each layer may be measured with respect to an electron micrograph of a cross section.

### EXAMPLES

The present disclosure will be described in greater detail with reference to the following EXAMPLES.

In EXAMPLE 1 and COMPARATIVE EXAMPLES 1 to 5, operations were performed to form photoelectric conversion films. The photoelectric conversion films formed were tested to evaluate the carrier life of the photoelectric conversion films.

The photoelectric conversion films formed in EXAMPLE 1 and COMPARATIVE EXAMPLE 1 were analyzed to determine the components of the photoelectric conversion film.

In EXAMPLE 2 and COMPARATIVE EXAMPLE 4, solar cells were fabricated. The solar cells fabricated were tested to determine the external quantum efficiency.

First, the configurations and the methods for formation of the photoelectric conversion films of EXAMPLES and COMPARATIVE EXAMPLES will be described.

### Example 1

Photoelectric conversion films of EXAMPLES 1-1 to 1-6 were formed by the following method.

A 24.5 mm square glass substrate with a thickness of 0.7 mm (manufactured by Nippon Sheet Glass Co., Ltd.) was provided as a substrate.

Next, a seed layer was formed on the substrate. The seed layer was formed by a coating method. A first solution for forming the seed layer was prepared which was a dimethylsulfoxide (DMSO) (manufactured by Sigma-Aldrich) solution containing 1 mol/L lead iodide (PbI₂) (manufactured by Tokyo Chemical Industry Co., Ltd.) and 1 mol/L methylammonium iodide (CH₃NH₃I) (manufactured by Greatcell Solar Materials).

Next, the first solution was applied onto the substrate by a spin coating method.

Thereafter, the substrate was heat-treated on a hot plate at 110° C. for 10 minutes to form a 300 nm thick seed layer on the substrate.

Subsequently, a photoelectric conversion film was formed. A second solution for forming the photoelectric conversion film was prepared which was a sulfolane (SLF) (manufactured by Tokyo Chemical Industry Co., Ltd.) solution containing PbI₂ (manufactured by Tokyo Chemical Industry Co., Ltd.) and formamidinium iodide (CH(NH₂)₂I) (manufactured by Greatcell Solar Materials). The HSP of SLF is described in Table 1. In the formation of photoelectric conversion films in EXAMPLES 1-1 to 1-6, the PbI₂ concentrations and the CH(NH₂)₂I concentrations in the second solutions, that is, the concentrations of FAPbI₃ in the second solutions are described in Table 2.

Next, the second solution and the substrate having the seed layer were each heated. In the formation of photoelectric conversion films in EXAMPLES 1-1 to 1-6, the heating temperatures for the second solution and the substrate are described in Table 2. Thereafter, the surface of the seed layer on the substrate that had been heated was brought into contact with the surface of the heated second solution for 1 second. Consequently, the seed layer was replaced by FAPbI₃ that was precipitated. Photoelectric conversion films including FAPbI₃ were thus obtained. FAPbI₃ was identified as α-phase by XRD measurement. CuKα ray was used as the X-ray.

### Example 2

In EXAMPLE 2, a solar cell 300 illustrated in FIG. 5 was fabricated. The solar cell 300 of EXAMPLE 2 had the following components:

Substrate 101: Glass substrate (thickness: 0.7 mm)
First electrode 102: Indium-tin composite oxide
Electron transport layer 105: Bilayer film of titanium dioxide (thickness: 12 nm) and porous titanium dioxide (thickness: 150 nm)
Photoelectric conversion layer 103: FAPbI₃ (thickness: 4000 nm)
Hole transport layer 106: 2,2′,7,7′-Tetrakis-(N,N-di-p-methoxyphenylamine) 9,9′-spirobifluorene (hereinafter, “spiro-OMeTAD”) (thickness: 170 nm)
Second electrode 104: Gold (thickness: 170 nm)

The solar cell 300 of EXAMPLE 2 was fabricated as follows.

First, a substrate was provided in which a transparent conductive layer serving as a first electrode 102 was disposed on the surface of a glass substrate serving as a substrate 101. The substrate provided in this example was a 0.7 mm thick conductive glass substrate (surface resistance: 10Ω/□, manufactured by Nippon Sheet Glass Co., Ltd.) having an indium-tin composite oxide layer on the surface.

Next, an electron transport layer 105 was formed. A dense titanium dioxide film was formed on the conductive glass substrate by a sputtering method. An electron transport layer solution for forming a porous titanium dioxide layer as a constituent of the electron transport layer 105 was prepared. This electron transport layer solution was prepared by dispersing porous titanium dioxide (product name: NR30D, manufactured by Greatcell Solar Materials) in ethanol in a concentration of 150 g/L. The electron transport layer solution was applied onto the dense titanium dioxide film by a spin coating method to form a coating film. The coating film was heated in an oven at 500° C. for 30 minutes. An electron transport layer 105 was thus formed.

Subsequently, a photoelectric conversion layer 103 was formed. A first solution for forming a seed layer on the electron transport layer 105 was prepared. While the first solution used in EXAMPLE 1 was a DMSO solution containing PbI₂ and CH₃NH₃I, the first solution used here was a mixture of the following solutions A, B and C.

The solution A was a solution prepared so as to include 1.1 mol/L lead iodide (PbI₂) (manufactured by Tokyo Chemical Industry Co., Ltd.), 1 mol/L formamidinium iodide (CH(NH₂)₂I) (manufactured by Greatcell Solar Materials), 0.22 mol/L lead bromide (PbBr₂) (manufactured by Tokyo Chemical Industry Co., Ltd.) and 0.2 mol/L methylammonium bromide (MABr) (manufactured by Greatcell Solar Materials). The solvent in the solution A was a mixed solvent including dimethylformamide (DMF) (manufactured by Sigma-Aldrich) and dimethyl sulfoxide (DMSO) (manufactured by Sigma-Aldrich) in a ratio (by volume) of 4:1.

The solution B was a DMSO solution prepared so as to include 1.5 mol/L cesium iodide (CsI) (manufactured by Sigma-Aldrich).

The solution C was a solution prepared so as to include 1.5 mol/L rubidium iodide (RbI) (manufactured by Sigma-Aldrich). The solvent in the solution C was a mixed solvent including DMF and DMSO in a volume ratio of 4:1.

The solution A, the solution B and the solution C were mixed together in a ratio (by volume) of solution A:solution B:solution C=90:5:5 to give the first solution.

Next, the first solution was applied onto the electron transport layer 105 by a spin coating method. The stack composed of the substrate 101, the first electrode 102 and the electron transport layer 105 served as the substrate for forming a seed layer. During this process, 200 μL of chlorobenzene (manufactured by Sigma-Aldrich) as a poor solvent was dropped onto the stack, specifically, the electron transport layer 105 being rotated.

Thereafter, the stack was heat-treated on a hot plate at 115° C. for 10 minutes and was further heat-treated on a hot plate at 100° C. for 30 minutes. Thus, a 400 nm thick seed layer was formed on the electron transport layer 105 in the stack.

Using this seed layer, a photoelectric conversion film as a photoelectric conversion layer 103 was formed in the same manner as in EXAMPLE 1. In the formation of photoelectric conversion film in EXAMPLE 2, the PbI₂ concentration and the CH(NH₂)₂I concentration in the second solution, that is, the concentration of FAPbI₃ in the second solution is described in Table 2. In the formation of photoelectric conversion film in EXAMPLE 2, the heating temperature for the substrate (the stack) and the second solution at the time of contact of the surface of the seed layer with the second solution was 125° C.

Subsequently, a hole transport layer 106 was formed on the photoelectric conversion layer 103. The hole transport layer 106 was formed by applying a toluene solution containing 45 mg/mL spiro-OMeTAD (manufactured by Tokyo Chemical Industry Co., Ltd.) onto the photoelectric conversion layer 103 by spin coating. The thickness of the hole transport layer 106 was 170 nm.

Lastly, gold was deposited onto the hole transport layer 106 to a thickness of 170 nm to form a second electrode 104. A solar cell 300 of EXAMPLE 2 was thus obtained.

### Comparative Example 1

Photoelectric conversion films of COMPARATIVE EXAMPLES 1-1 to 1-7 were formed by the following method.

In COMPARATIVE EXAMPLES 1-1 to 1-7, γ-butyrolactone (GBL) (manufactured by Wako Pure Chemical Industries, Ltd.) was used in place of SLF as the solvent in the second solution for forming a photoelectric conversion film. The HSP of GBL is described in Table 1. Photoelectric conversion films including FAPbI₃ of COMPARATIVE EXAMPLES 1-1 to 1-7 were formed through the same steps as in EXAMPLE 1, except that the solvent in the second solution was different. In the formation of photoelectric conversion films of COMPARATIVE EXAMPLES 1-1 to 1-7, the concentrations of PbI₂ and the concentrations of CH(NH₂)₂I in the second solutions, that is, the concentrations of FAPbI₃ in the second solutions are described in Table 2. The heating temperature for the second solution and the base, and the time of contact between the seed layer and the second solution are described in Table 2.

### Comparative Example 2

Photoelectric conversion films of COMPARATIVE EXAMPLES 2-1 to 2-4 were formed by the following method.

In COMPARATIVE EXAMPLES 2-1 to 2-4, γ-valerolactone (GVL) (manufactured by Wako Pure Chemical Industries, Ltd.) was used in place of SLF as the solvent in the second solution for forming a photoelectric conversion film. The HSP of GVL is described in Table 1. Photoelectric conversion films including FAPbI₃ of COMPARATIVE EXAMPLES 2-1 to 2-4 were formed through the same steps as in EXAMPLE 1, except that the solvent in the second solution was different. In the formation of photoelectric conversion films of COMPARATIVE EXAMPLES 2-1 to 2-4, the PbI₂ concentrations and the CH(NH₂)₂I concentrations in the second solutions, that is, the concentrations of FAPbI₃ in the second solutions are described in Table 2. The heating temperature for the second solution and the base, and the time of contact between the seed layer and the second solution are described in Table 2.

### Comparative Example 3

A photoelectric conversion film of COMPARATIVE EXAMPLE 3 was formed by the following method.

In COMPARATIVE EXAMPLE 3, γ-heptanolactone (GHL) (manufactured by Tokyo Chemical Industry Co., Ltd.) was used in place of SLF as the solvent in the second solution for forming a photoelectric conversion film. The HSP of GHL falls in the range described in Table 1. A photoelectric conversion film was formed through the same steps as in EXAMPLE 1, except that the solvent in the second solution was different. In the formation of photoelectric conversion film of COMPARATIVE EXAMPLE 3, the PbI₂ concentration and the CH(NH₂)₂I concentration in the second solution, that is, the concentration of FAPbI₃ in the second solution is described in Table 2. The heating temperature for the second solution and the base, and the time of contact between the seed layer and the second solution are described in Table 2.

In COMPARATIVE EXAMPLE 3, contacting the surface of the seed layer on the heated substrate with the surface of the heated second solution resulted in dissolution and disappearance of the seed layer, and consequently FAPbI₃ was not precipitated. As a result, a photoelectric conversion film including FAPbI₃ was not obtained.

### Comparative Example 4

A photoelectric conversion film of COMPARATIVE EXAMPLE 4 was formed by the following method.

In COMPARATIVE EXAMPLE 4, γ-decanolactone (GDL) (manufactured by Tokyo Chemical Industry Co., Ltd.) was used in place of SLF as the solvent in the second solution for forming a photoelectric conversion film. The HSP of GDL falls in the range described in Table 1. A photoelectric conversion film was formed through the same steps as in EXAMPLE 1, except that the solvent in the second solution was different. In the formation of photoelectric conversion film of COMPARATIVE EXAMPLE 4, the PbI₂ concentration and the CH(NH₂)₂I concentration in the second solution, that is, the concentration of FAPbI₃ in the second solution is described in Table 2. The heating temperature for the second solution and the base, and the time of contact between the seed layer and the second solution are described in Table 2.

In COMPARATIVE EXAMPLE 4, contacting the surface of the seed layer on the heated substrate with the surface of the heated second solution resulted in dissolution and disappearance of the seed layer, and consequently FAPbI₃ was not precipitated. As a result, a photoelectric conversion film including FAPbI₃ was not obtained.

### Comparative Example 5

Photoelectric conversion films of COMPARATIVE EXAMPLES 5-1 to 5-4 were formed by the following method.

As a substrate, a 24.5 mm square glass substrate having a thickness of 0.7 mm was provided.

A dimethyl sulfoxide (DMSO) (manufactured by Sigma-Aldrich) solution was prepared which included lead iodide (PbI₂) (manufactured by Tokyo Chemical Industry Co., Ltd.) and formamidinium iodide (CH(NH₂)₂I) (manufactured by Greatcell Solar Materials). The HSP of DMSO is described in Table 1. In the formation of photoelectric conversion films of COMPARATIVE EXAMPLES 5-1 to 5-4, the PbI₂ concentrations and the CH(NH₂)₂I concentrations in the DMSO solutions, that is, the concentrations of FAPbI₃ in the DMSO solutions are described in Table 2. Photoelectric conversion films including FAPbI₃ were formed on the substrate by applying the DMSO solution onto the substrate and heat-treating the coating in the same manner as in the formation of the seed layer in EXAMPLE 1.

### Comparative Example 6

In COMPARATIVE EXAMPLE 6, a solar cell 300 illustrated in FIG. 5 was fabricated. The solar cell 300 of COMPARATIVE EXAMPLE 6 was fabricated in the same manner as the solar cell 300 of EXAMPLE 2, except that the solvent in the second solution for forming a photoelectric conversion film was changed from SLF to γ-butyrolactone (GBL) (manufactured by Wako Pure Chemical Industries, Ltd.).

### <HSP of Solvents>

The HSP of the solvents used to prepare the photoelectric conversion films of EXAMPLE 1, COMPARATIVE EXAMPLE 1 and COMPARATIVE EXAMPLE 5 were the values described in Reference 1: “Charles M. Hansen, “HANSEN SOLUBILITY PARAMETERS A User's Handbook”, Second Edition (2007, CRC Press)”. The HSP of the solvent used to prepare the photoelectric conversion film of COMPARATIVE EXAMPLE 2 were cited from Reference 2: “H. J. Salavagione et al., “Identification of high performance solvents for the sustainable processing of graphene”, Green Chemistry, 2017, 19, pp. 2550-2560 (The Royal Society of Chemistry)”. The ranges of the HSP of the solvents used in COMPARATIVE EXAMPLE 3 and COMPARATIVE EXAMPLE 4 were estimated based on the description in Reference 1. More specifically, the influence that would be exerted by the alkyl group was studied based on the HSP values in the case of γ-lactone (the basic skeleton common to GHL and GDL) with reference to Table 1.1, Group Contributions to Partial Solubility Parameters described on pages 10 and 11 of Reference 1. The HSP values of GHL and GDL were thus estimated. The results are summarized in Table 1.

TABLE 1

| | | Hansen solubility parameters (HSP) | | |
|---|---|---|---|---|
| | | Dispersion | Polar | Hydrogen |
| | | term δ_{D} | term δ_{P} | bonding term |
| | Solvent | [MPa^{2.5}] | [MPa^{0.5}] | δ_{H} [MPa^{0.5}] |
| EXAMPLE 1 | SLF | 20.3 | 18.2 | 10.8 |
| COMPARATIVE | GBL | 18.0 | 16.6 | 7.4 |
| EXAMPLE 1 | | | | |
| COMPARATIVE | GVL | 16.9 | 11.5 | 6.3 |
| EXAMPLE 2 | | | | |
| COMPARATIVE | GHL | 19.5< | 18< | <7 |
| EXAMPLE 3 | | | | |
| COMPARATIVE | GDL | 19.5< | 18< | <7 |
| EXAMPLE 4 | | | | |
| COMPARATIVE | DMSO | 18.4 | 16.4 | 10.2 |
| EXAMPLE 5 | | | | |

### <Measurement of Film Thickness H of Photoelectric Conversion Films>

The film thickness H of the photoelectric conversion films of EXAMPLES 1 and 2 and COMPARATIVE EXAMPLES 1 to 5 was measured as follows. Using DekTak (manufactured by Bruker Japan K.K.), 500 μm wide profiles were measured and assessed to determine three average heights from the substrate, and the three average heights were further averaged to calculate the film thickness H of the photoelectric conversion film. The results are described in Table 2. The three average heights that were measured are the average height at points in the center of the substrate, the average height at points 7 mm to the left from the center of the substrate, and the average height at points 7 mm to the right from the center of the substrate.

### <Measurement of Root Mean Square Roughness Rq of Photoelectric Conversion Films>

The root mean square roughness Rq of the photoelectric conversion films of EXAMPLES 1 and 2 and COMPARATIVE EXAMPLES 1 to 5 was measured as follows. Using DekTak (manufactured by Bruker Japan K.K.), three 500 μm wide profiles were measured. The three profiles were assessed to determine the root mean square roughnesses, which were then averaged to determine the root mean square roughness Rq of the photoelectric conversion film. The results are described in Table 2.

### <Relationship Between Film Thickness H and Root Mean Square Roughness Rq>

Using the film thickness H and the root mean square roughness Rq measured by the above methods, the ratio of the root mean square roughness Rq to the film thickness H (hereinafter, written as “Rq/H”) was calculated. The results are described in Table 2.

### <SEM Images of Cross Sections of Photoelectric Conversion Films>

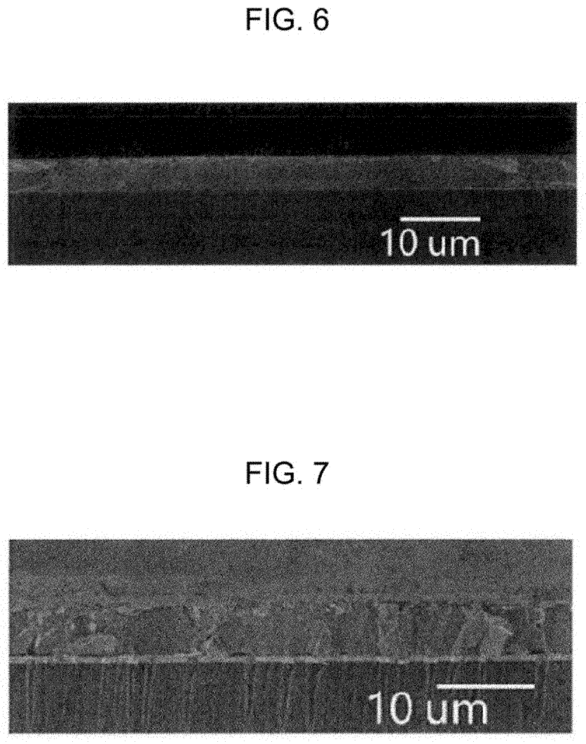

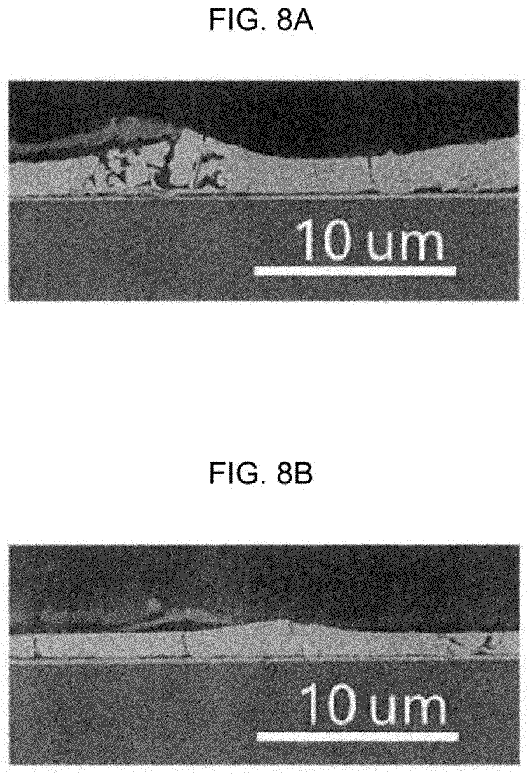

FIG. 6 illustrates a SEM image of a cross section of the photoelectric conversion film of EXAMPLE 1-1. FIG. 7 illustrates a SEM image of a cross section of the photoelectric conversion film of COMPARATIVE EXAMPLE 1-4. FIG. 8A illustrates a SEM image of a cross section of the photoelectric conversion film of COMPARATIVE EXAMPLE 5-2. FIG. 8B illustrates a SEM image of a cross section of the photoelectric conversion film of COMPARATIVE EXAMPLE 5-2. The SEM images in FIGS. 8A and 8B are of cross sections at different locations of the photoelectric conversion film.

As can be seen from FIGS. 6 and 7, the photoelectric conversion films formed by the methods described in EXAMPLE 1 and COMPARATIVE EXAMPLE 1 had small surface roughness and a substantially uniform film thickness in spite of the film thickness being large. In contrast, as can be seen from FIGS. 8A and 8B, the observation showed that the thick photoelectric conversion film formed by the method described in COMPARATIVE EXAMPLE 5 had varied film thicknesses distributed depending on locations, and the surface roughness was large. As clear from here and also from the results of the measurement of the root mean square roughness Rq described in Table 2, the photoelectric conversion films of EXAMPLE 1 and COMPARATIVE EXAMPLE 1 attained small surface roughness compared to the photoelectric conversion film of COMPARATIVE EXAMPLE 5. Further, from the SEM images of FIGS. 6 and 7, the seed layer had disappeared in the photoelectric conversion films of EXAMPLE 1-1 and COMPARATIVE EXAMPLE 1-4, and the photoelectric conversion films obtained were uniform.

### <Carrier Life>

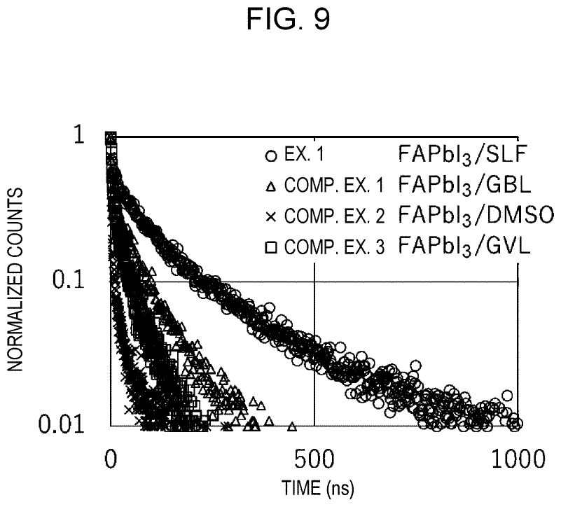

The carrier life in the photoelectric conversion films of EXAMPLE and COMPARATIVE EXAMPLES was determined from fluorescence attenuation curves. Using a near-infrared fluorescence lifetime measuring device (C7990 manufactured by Hamamatsu Photonics K.K.), the photoelectric conversion film formed on the glass substrate was analyzed to measure the fluorescence lifetime. A laser beam was incident on the photoelectric conversion film side under conditions of an excitation wavelength of 840 nm, an excitation output to the sample of less than or equal to 50 mW, and a peak count of 1000. The fluorescence attenuation curve measurement was performed for the photoelectric conversion films of EXAMPLE 1-2, COMPARATIVE EXAMPLE 1-4, COMPARATIVE EXAMPLE 2-2 and COMPARATIVE EXAMPLE 5-4. FIG. 9 illustrates the fluorescence attenuation curves of the photoelectric conversion films of EXAMPLE 1-2, COMPARATIVE EXAMPLE 1-4, COMPARATIVE EXAMPLE 2-2 and COMPARATIVE EXAMPLE 5-4. In FIG. 9, the abscissa is the time and the ordinate the counts normalized from the peak counts.

From the fluorescence attenuation curve, lifetimes τ₁ (including the laser light component) and τ₂ were determined by two-component analysis:

A=A₁ exp(−t/τ₁)+A₂ exp(−τ/τ₂)

Here, A, A₁ and A₂ denote the fluorescence intensity and the intensities of respective components, and t represents the time. The first component A₁exp(−t/τ₁) included the superimposed pulse of the time waveform of the laser used for excitation. Thus, the carrier lifetimes were compared using the lifetime τ₂ of the second component A₂exp(−t/τ₂). The calculation results are described in Table 3.

Provided that a photoelectric conversion film includes FAPbI₃ as a principal component and the carrier life is about 100 ns, the optimum film thickness of the photoelectric conversion film that will allow for the collection of generated carriers is usually about 1 μm at the largest. Thus, even when the photoelectric conversion film is increased in film thickness to greater than or equal to 1 μm to absorb more light, the generated carriers cannot be taken out sufficiently from the electrode layers.

In contrast, the photoelectric conversion film of EXAMPLE 1-2 which had a film thickness of about 2.5 μm attained a carrier life of 420 ns. On the other hand, the carrier lifetimes of the photoelectric conversion films of COMPARATIVE EXAMPLES 1-4, 2-2 and 5-4 were as short as less than or equal to 120 ns. These results show that, by virtue of the use as a solvent of a substance having HSP satisfying a dispersion term δ_{D} of 20±0.5 MPa^{0.5}, a polar term δ_{P} of 18±1 MPa^{0.5} and a hydrogen bonding term δ_{H} of 11±2 MPa^{0.5}, the photoelectric conversion film of EXAMPLE 1-2 in spite of being thick had a carrier life approximately four times as long as that of the photoelectric conversion film of COMPARATIVE EXAMPLE formed using a solvent failing to satisfy the above HSP.

TABLE 2

| | | | | FAPbI₃ | Time of contact | | | |
|---|---|---|---|---|---|---|---|---|
| | | | Substrate | concentration | between seed | | Root mean | |
| | | Solvent | heating | in second | layer and | Film | square | |
| | | in second | temperature | solution | second solution | thickness H | roughness Rq | |
| | | solution | [° C.] | [mol/L] | [s] | [μm] | [μm] | Rq/H |
| Ex. 1 | 1-1 | SLF | 155 | 0.87 | 1 | 3.43 | 0.26 | 0.07 |
| | 1-2 | | 125 | 0.87 | 1 | 2.54 | 0.21 | 0.08 |
| | 1-3 | | 175 | 0.87 | 1 | 3.42 | 0.36 | 0.1 |
| | 1-4 | | 165 | 0.87 | 1 | 2.88 | 0.31 | 0.11 |
| | 1-5 | | 165 | 0.87 | 1 | 3.23 | 0.36 | 0.11 |
| | 1-6 | | 175 | 0.87 | 1 | 2.86 | 0.37 | 0.13 |
| Ex. 2 | 2 | SLF | 125 | 0.85 | 2 | — | — | — |
| Comp. Ex. 1 | 1-1 | GBL | 85 | 1.3 | 1 | 2.33 | 0.24 | 0.10 |
| | 1-2 | | 95 | 1 | 1 | 2.05 | 0.16 | 0.08 |
| | 1-3 | | 100 | 1 | 1 | 3.97 | 0.24 | 0.06 |
| | 1-4 | | 100 | 0.9 | 1 | 3.05 | 0.22 | 0.07 |
| | 1-5 | | 100 | 0.8 | 1 | 2.28 | 0.23 | 0.10 |
| | 1-6 | | 135 | 0.69 | 1 | 2.42 | 0.22 | 0.09 |
| | 1-7 | | 155 | 0.62 | 1 | 2.61 | 0.28 | 0.11 |
| Comp. Ex. 2 | 2-1 | GVL | 67 | 0.7 | 1 | 1.63 | 0.1 | 0.06 |
| | 2-2 | | 95 | 0.7 | 1 | 2.7 | 0.22 | 0.08 |
| | 2-3 | | 85 | 0.7 | 30 | 10.5 | 1.18 | 0.11 |
| | 2-4 | | 95 | 0.7 | 30 | 6.9 | 0.91 | 0.13 |
| Comp. Ex. 3 | 3 | GHL | 60 | 0.44 | 1 | — | — | — |
| Comp. Ex. 4 | 4 | GDL | 80 | 0.25 | 1 | — | — | — |
| Comp. Ex. 5 | 5-1 | DMSO | — | 1.5 | — | 0.64 | 0.23 | 0.36 |
| | 5-2 | | — | 2 | — | 1.06 | 0.38 | 0.36 |
| | 5-3 | | — | 2.5 | — | 1.88 | 0.47 | 0.25 |
| | 5-4 | | — | 3 | — | 2.61 | 0.67 | 0.26 |
| Comp. Ex. 6 | 6 | GBL | 105 | 1 | 1 | 3.67 | 0.28 | 0.08 |

TABLE 3

| | Film thickness [μm] | Carrier life [ns] |
|---|---|---|
| EXAMPLE 1-2 | 2.54 | 420 |
| COMPARATIVE EXAMPLE 1-4 | 3.05 | 120 |
| COMPARATIVE EXAMPLE 2-2 | 2.7 | 60 |
| COMPARATIVE EXAMPLE 5-4 | 2.61 | 34 |

### <Component Analysis>

The substances contained in the photoelectric conversion films of EXAMPLE 1-1 and COMPARATIVE EXAMPLE 1-4 were quantitatively determined by a GC/MS method. “GCMS-QP2010 Plus” (manufactured by Shimadzu Corporation) was used as a GC/MS device, and “ZB-FFAP (30 m×0.32 mm×0.50 μm)” was used as a column. The column heating conditions were such that the temperature was raised to 40° C. in 3 minutes, then raised to 240° C. at a rate of 10° C./min and held at the temperature for 7 minutes. Helium gas was used as a carrier gas. The helium gas was supplied at a rate of 2.02 mL/min. The measurement sample was injected by a splitless method. At an injection port temperature of 200° C. and a detector temperature of 230° C., scan analysis (m/z=33-600) and selective ion analysis (SLF: three m/z values=41, 56 and 120, GBL: three m/z values=42, 56 and 86, DMSO: two m/z values=63 and 78).

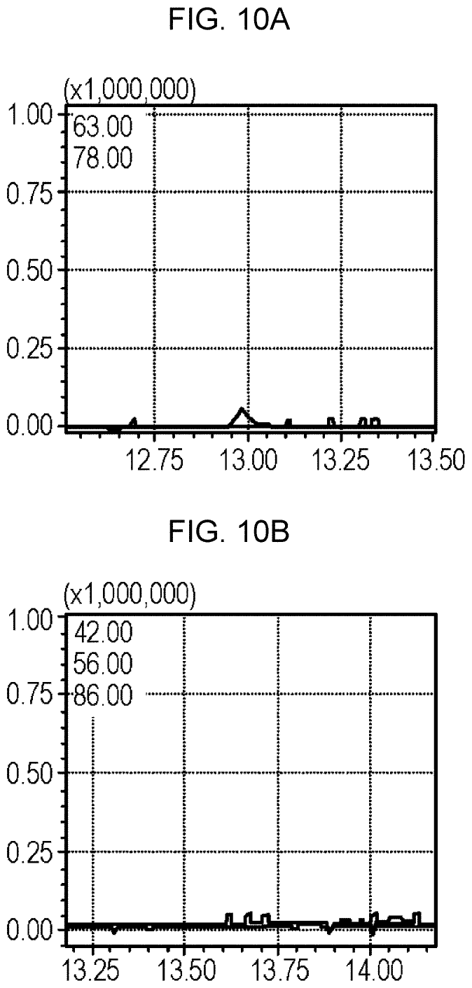

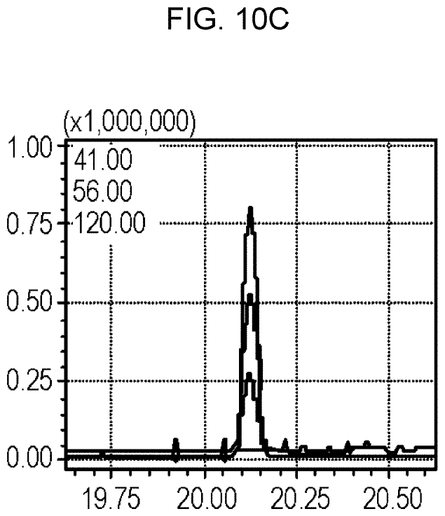

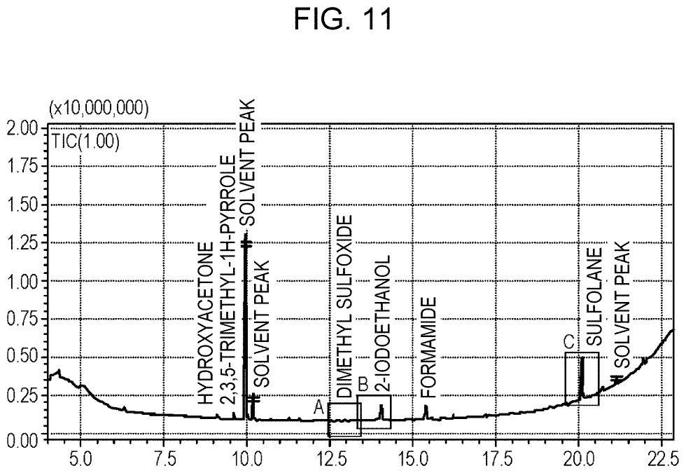

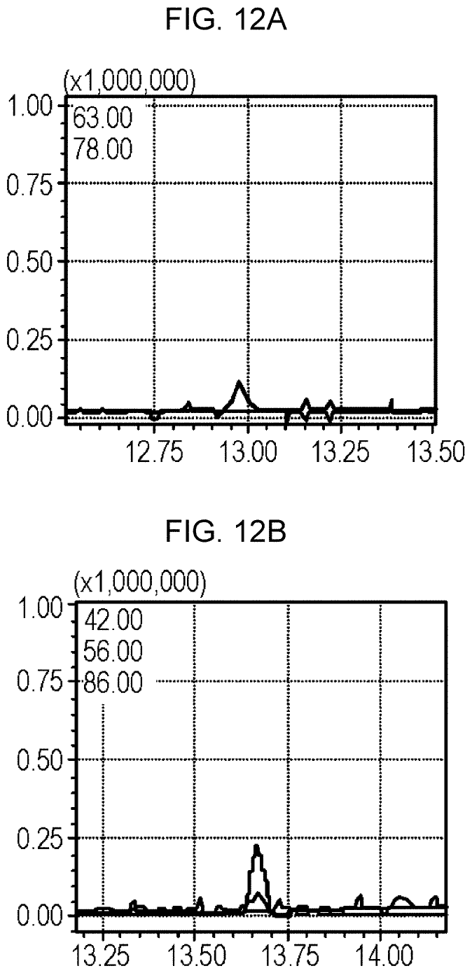

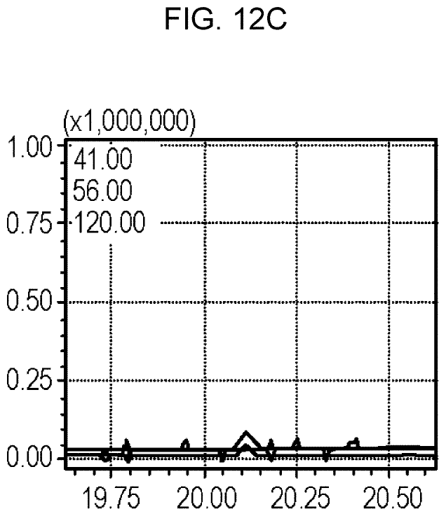

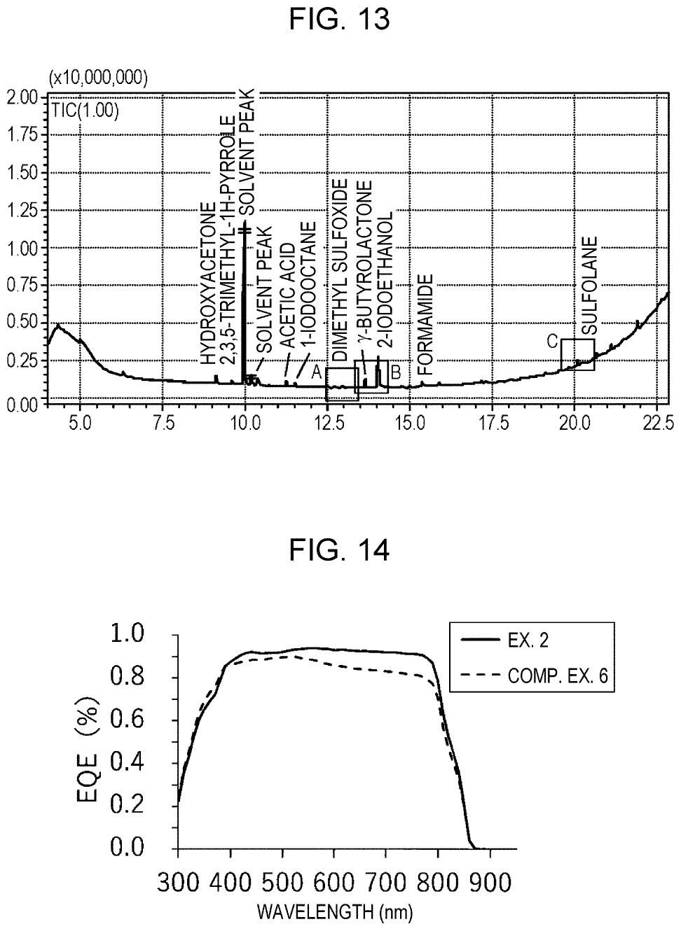

The 24.5 mm square, 0.7 mm thick glass substrate bearing the photoelectric conversion film to be analyzed was immersed in 2 mL of acetone to extract the photoelectric conversion film. The extract obtained was used as a measurement sample. The measurement sample was analyzed on the GC/MS device to perform quantitative analysis (selective ion analysis) of SLF, GBL and DMSO, and qualitative and quantitative analysis (scan analysis) of substances that were contained. The quantification in the scan analysis was performed by calculation using toluene d8 as a standard material. FIG. 10A illustrates the results of selective ion analysis of dimethyl sulfoxide by the GC/MS method with respect to the photoelectric conversion film of EXAMPLE 1-1. FIG. 10B illustrates the results of selective ion analysis of γ-butyrolactone by the GC/MS method with respect to the photoelectric conversion film of EXAMPLE 1-1. FIG. 10C illustrates the results of selective ion analysis of sulfolane by the GC/MS method with respect to the photoelectric conversion film of EXAMPLE 1-1. FIG. 11 illustrates the results of scan analysis of the photoelectric conversion film of EXAMPLE 1-1 by the GC/MS method. FIG. 12A illustrates the results of selective ion analysis of dimethyl sulfoxide by the GC/MS method with respect to the photoelectric conversion film of COMPARATIVE EXAMPLE 1-4. FIG. 12B illustrates the results of selective ion analysis of γ-butyrolactone by the GC/MS method with respect to the photoelectric conversion film of COMPARATIVE EXAMPLE 1-4. FIG. 12C illustrates the results of selective ion analysis of sulfolane by the GC/MS method with respect to the photoelectric conversion film of COMPARATIVE EXAMPLE 1-4. FIG. 13 illustrates the results of scan analysis of the photoelectric conversion film of COMPARATIVE EXAMPLE 1-4 by the GC/MS method.

Table 4 describes the results of quantification of the substances contained in the photoelectric conversion films by the above analysis. From the photoelectric conversion film of EXAMPLE 1-1, 0.1 mol % SLF and 0.01 mol % DMSO were detected. From the photoelectric conversion film of COMPARATIVE EXAMPLE 1-4, 0.05 mol % GBL and 0.02 mol % DMSO were detected. The reasons behind these results are probably because as indicated by HSP, SLF has a high tendency to form a complex with FAPbI₃ among ITC solvents and is easily incorporated into the crystal structure of FAPbI₃. The number density of the incorporated molecules corresponds to 3.8×10¹⁸ molecules/cm³. As demonstrated here, the photoelectric conversion film of EXAMPLE 1-1 had incorporated molecules of the solvent during the crystal growth in the formation of the photoelectric conversion film. The crystal structure of FAPbI₃ includes lattice defects. Such lattice defects serve as recombination sites by capturing photoinduced carriers to cause a decrease in carrier life. Provided that the density of defective sites is 10¹⁸ defects/cm³, the carrier life will be about 20 ns at the longest. To realize a carrier life of about 400 ns as is the case in the photoelectric conversion film of EXAMPLE 1-1, it will be necessary that the defect density be less than or equal to about 10¹⁰ defects/cm³ at most. Probably, the SLF molecules in the photoelectric conversion film are present complementarily with lattice defects so as to prevent the photoinduced carriers from being captured by the lattice defects, and thereby lower the recombination probability and contribute to the extension of carrier life.

TABLE 4

| | EXAMPLE 1-1 | | | COMPARATIVE EXAMPLE 1-4 | | |
|---|---|---|---|---|---|---|
| | SLF | GBL | DMSO | SLF | GBL | DMSO |
| Content (μg/cm²) | 0.23 | — | 0.01 | — | 0.08 | 0.02 |
| Molar ratio (%) | 0.1 | — | 0.01 | — | 0.05 | 0.02 |
| Number density | 3.8 | — | 0.4 | — | 1.9 | 0.7 |
| (10¹⁸ molecules/cm³) | | | | | | |

The above results confirmed that the photoelectric conversion film of EXAMPLE 1-1 contained the substance (A) which had HSP satisfying a dispersion term δ_{D} of 20±0.5 MPa^{0.5}, a polar term δ_{P} of 18±1 MPa^{0.5} and a hydrogen bonding term δ_{H} of 11±2 MPa^{0.5}. That is, it has been shown that a photoelectric conversion film produced using as a solvent a substance (A) satisfying the above HSP contains the substance (A) after the photoelectric conversion film has been formed. Furthermore, it has been shown that a photoelectric conversion film containing a substance (A) may attain a long carrier life even when the photoelectric conversion film has a large film thickness.

### <Measurement of External Quantum Efficiency>

The external quantum efficiency (hereinafter, also written as “EQE”) was measured of the solar cells of EXAMPLE 2 and COMPARATIVE EXAMPLE 6. FIG. 14 is a graph illustrating relationships between the incident light wavelength and the EQE in the solar cells of EXAMPLE 2 and COMPARATIVE EXAMPLE 6. The abscissa in the graph of FIG. 14 indicates the incident light wavelength, and the ordinate the EQE. The bias voltage was 1 V. Table 5 describes the short-circuit current densities (mA/cm²) obtained by integrating the EQE. As can be seen from these results, the photoelectric conversion layer in the solar cell of EXAMPLE 2 can absorb extra light in the band of 1.4 to 1.5 eV owing to having a large film thickness, and has a long carrier recombination life to allow an increased amount of charge carriers photoelectrically converted in the long wavelength band to be taken out as electricity.

TABLE 5

| | Short-circuit current density [mA/cm²] |
|---|---|
| EXAMPLE 2 | 26.4 |
| COMPARATIVE EXAMPLE 6 | 24.6 |

As described hereinabove, the photoelectric conversion films of the present disclosure may attain a long carrier life even when formed with an increased film thickness. The photoelectric conversion films of the present disclosure can absorb light in a wider band by virtue of the increase in film thickness and still has a long carrier life. Thus, the photoelectric conversion films of the present disclosure are suited for the fabrication of highly efficient solar cells.

The photoelectric conversion film of the present disclosure can concurrently attain a high light absorption ability and a long carrier life, and thus may be used as a photoelectric conversion layer in a highly efficient solar cell.

What is claimed is:

1. A photoelectric conversion film comprising:
an α-phase perovskite compound comprising a monovalent formamidinium cation, a Pb cation and an iodide ion; and
a substance having Hansen solubility parameters satisfying a dispersion term δp of 20±0.5 MPa^{0.5}, a polar term δ_{P} of 18±1 MPa^{0.5} and a hydrogen bonding term δ_{H} of 11±2 MPa^{0.5}.

2. The photoelectric conversion film according to claim 1, wherein
the substance is at least one selected from the group consisting of sulfolane and maleic anhydride.

3. The photoelectric conversion film according to claim 2, wherein
the substance is sulfolane, and
the photoelectric conversion film has peaks at m/z=41, 56 and 120 when analyzed by a gas chromatography mass spectrometry method.

4. The photoelectric conversion film according to claim 1, wherein
the content of the substance is less than or equal to 0.1 mol %.

5. A solar cell comprising:
a first electrode;
a second electrode; and
a photoelectric conversion layer disposed between the first electrode and the second electrode, wherein
at least one electrode selected from the group consisting of the first electrode and the second electrode has translucency, and
the photoelectric conversion layer is the photoelectric conversion film described in claim 1.

6. The solar cell according to claim 5, further comprising:
an electron transport layer disposed between the first electrode and the photoelectric conversion layer.

7. The solar cell according to claim 5, further comprising:
a hole transport layer disposed between the second electrode and the photoelectric conversion layer.

8. A method for producing a photoelectric conversion film, comprising:
(A) applying a first solution including elements for constituting a first perovskite compound to a substrate to form a seed layer including the first perovskite compound; and
(B) heating the substrate and bringing a second solution into contact with the surface of the seed layer on the substrate to precipitate a second perovskite compound, thereby producing a photoelectric conversion film, wherein
the second solution includes elements for constituting the second perovskite compound, and a solvent,
the elements for constituting the second perovskite compound include a monovalent formamidinium cation, a Pb cation and an iodide ion, and
the solvent comprises a substance having Hansen solubility parameters satisfying a dispersion term δ_{D} of 20±0.5 MPa^{0.5}, a polar term δ_{P} of 18±1 MPa^{0.5} and a hydrogen bonding term δ_{H} of 11±2 MPa^{0.5}.
